(19) United States
(12) Patent Application Publication
(10) Pub. No.: US 2012/0025182 A1
(43) Pub. Date: Feb. 2, 2012

(54) DONOR SUBSTRATE, PROCESS FOR PRODUCTION OF TRANSFER FILM, AND PROCESS FOR PRODUCTION OF ORGANIC ELECTROLUMINESCENT ELEMENT

(75) Inventors: Tokiyoshi Umeda, Osaka (JP); Hideki Uchida, Osaka (JP)

(73) Assignee: SHARP KABUSHIKI KAISHA, Osaka (JP)

(21) Appl. No.: 13/259,381

(22) PCT Filed: Dec. 8, 2009
(86) PCT No.: PCT/JP2009/070558

§ 371 Date: Sep. 23, 2011

(30) Foreign Application Priority Data
Apr. 3, 2009 (JP) 2009-090955

(51) Int. Cl. H01L 51/52; H01L 51/56; H01L 51/00

(52) U.S. Cl. 257/40; 438/99; 438/46; 257/E51.001; 257/E51.018

(57) ABSTRACT

The present invention provides a donor substrate, a process for production of a transfer film, and a process for production of an organic electroluminescent element, that allow obtaining a transfer film having a uniform composition distribution by way of a simple configuration. A donor substrate of the present invention is a substrate comprising a photothermal conversion layer and a donor layer, wherein the donor layer has a first organic layer arranged on a side of a transfer surface, and a second organic layer arranged on a side of the photothermal conversion layer; the first organic layer and the second organic layer are formed of vaporizable organic materials having dissimilar vaporization-starting temperatures; and the organic material that forms the first organic layer has a vaporization-starting temperature higher than that of the organic material that forms the second organic layer.

### TECHNICAL FIELD

The present invention relates to a donor substrate, a process for production of a transfer film, and a process for production of an organic electroluminescent element. More particularly, the present invention relates to a donor substrate that uses a thermal transfer method, a process for production of a transfer film using the donor substrate, and a process for production of an organic electroluminescent element using the process for production of a transfer film.

### BACKGROUND ART

Display devices that use organic electroluminescent elements are widely used as display devices in, for instance, TVs, PC displays, mobile terminal displays and the like. Such display devices must be capable of coping with ever smaller and thinner elements and larger display sizes. Organic electroluminescent elements have a configuration in which thin films, such as emissive layers, hole-transport layers and electron-transport layers are provided between an anode and a cathode. These thin films are formed of organic materials. Known methods in processes for production of such thin films include, for instance, vacuum evaporation, ink-jet methods, thermal transfer and the like.

Among the abovementioned processes for production of thin films, vacuum evaporation makes it difficult to achieve patterning with high positional precision, and to achieve high definition, on account of deflection and stretching of a shadow mask (opening mask). Vacuum evaporation cannot easily cope with ever smaller and thinner elements. On the other hand, larger elements entail not only larger and heavier frames that hold shadow masks, as well as larger and more complex equipment for handling the frames, but also problems in terms of safety in the manipulations involved in the production process. Therefore, patterning large substrates using large shadow masks is very difficult.

In ink-jet methods, mixed colors are likely to occur across adjacent pixels during patterning, as pixels become smaller as a result of the trend towards ever smaller and thinner elements. Also, liquid fixing positions must be controlled, among other requirements, and hence ink-jet methods have limitations as regards patterning precision. Organic luminescent materials comprising polymers are ordinarily used in ink-jet methods. However, such materials are difficult to develop, and currently exhibit poorer emission characteristics, and shorter lives, than organic luminescent materials that comprise low-molecular compounds.

If an ink-jet method is used, some means must be devised for preventing an underlayer from being dissolved by the solvent of the material that constitutes a top layer, from among the thin films that make up the emissive layers and so forth. This imposes constraints in that there cannot be used an arbitrary underlayer. Also, patterning of large substrates requires substantial takt time on account of the increased number of discharged droplets and expanded discharge area. Moreover, film thickness and film planarity vary significantly depending on the way in which the solvent of the discharged liquid is dried off, and hence such variability is likely to result in uneven display in the display device.

Among transfer methods that have been developed, transfer methods suitable for producing the above-mentioned thin films include, for instance, pattern formation methods by transfer using a light source, for instance laser beams. In such methods, transfer to a transfer receiving substrate (for instance, Patent Documents 2 and 3) is performed using a member called a donor substrate or donor sheet (Patent Document 1). An example is explained next of a method for forming a thin film using such a method.

Firstly, a donor substrate having a photothermal conversion layer and an organic donor layer formed thereon, and a substrate on which a film is to be formed having a first electrode, pixels and so forth formed thereon, are used by being disposed in such a manner that the organic donor layer of the donor substrate and the electrodes and so forth of the substrate on which a film is to be formed face each other. A laser beam is irradiated onto the photothermal conversion layer of the donor substrate, as a result of which the light energy absorbed by the photothermal conversion layer is converted to heat. The organic donor layer of a predetermined region is vaporized through scanning of the laser beam over a desired region, whereupon the patterned organic layer becomes transferred onto the substrate on which a film is to be formed. As a result, a thin film such as an emissive layer or the like can be selectively transferred to only a predetermined region on the first electrode.

### PRIOR ART REFERENCES

### Patent Documents

Patent Document 1: Specification of JP-B-3789991
Patent Document 2: JP-A-2006-309995
Patent Document 3: JP-A-2007-281159

The thin films that make up an organic electroluminescent element are often formed of a plurality of organic materials. When employing a pattern formation method by transfer using the abovementioned light sources, therefore, the donor layer of the donor substrate must be formed of a plurality of organic materials. However, transfer films obtained by donor layers in which a plurality of organic materials are uniformly mixed may exhibit in some cases a non-uniform material composition distribution. A non-uniform material composition distribution in the films that make up the emissive layers and so forth of an organic electroluminescent element exerts an influence on, for instance, element characteristic and luminous efficiency.

### DISCLOSURE OF THE INVENTION

In the light of the above, it is an object of the present invention to provide a donor substrate, a process for production of a transfer film, and a process for production of an organic electroluminescent element, that allow realizing a transfer film having a uniform composition distribution by way of a simple configuration.

As a result of various studies performed by the inventors on a donor substrate, a process for production of a transfer film, and a process for production of an organic electroluminescent element that allow realizing a transfer film having a uniform composition distribution by way of a simple configuration, the inventors came to focus on a feature wherein a layer formed of a readily vaporizable organic material, i.e. an organic material having a low vaporization-starting temperature, is disposed in a donor layer of a donor substrate, on the side of the transfer surface, and found that the composition distribution of the transfer film becomes uniform by virtue of such a feature. The inventors found also that building the donor layer by providing an organic layer formed of the organic material having the highest vaporization-starting temperature on the side of the transfer surface has the effect of arresting transfer, onto the transfer receiving substrate, of other organic materials even if the latter have reached a respective vaporization-starting temperature, until the former organic material has reached its vaporization-starting temperature. When this organic material reaches the vaporization-starting temperature, the other organic materials have already reached their respective vaporization-starting temperatures. As a result, it becomes possible for all the organic materials to reach the transfer receiving substrate substantially simultaneously, which allows achieving a uniform composition distribution in the obtained transfer film. The inventors found that the above problems could be admirably solved thereby, and arrived thus at the present invention.

Specifically, the present invention is a donor substrate comprising a photothermal conversion layer and a donor layer; wherein the donor layer has a first organic layer arranged on a side of a transfer surface, and a second organic layer arranged on a side of the photothermal conversion layer; the first organic layer and the second organic layer are formed of vaporizable organic materials having dissimilar vaporization-starting temperatures; and the organic material that forms the first organic layer has a vaporization-starting temperature higher than that of the organic material that forms the second organic layer.

The photothermal conversion layer, which converts radiation irradiated from outside into heat, has the function of imparting energy for vaporizing the organic layer. Radiation denotes electromagnetic waves that include light, heat and so forth. Herein there can be easily used, in particular, laser beams, or lamps such as xenon lamps or halogen lamps.

The donor layer has a first and a second organic layer that are each made up of a dissimilar material. The first organic layer is formed of an organic material having a higher vaporization-starting temperature than that of the organic material that forms the second organic layer. In the present invention, the vaporization-starting temperature denotes the temperature at the point in time at which weight is reduced by 5%, through vaporization, in a thermogravimetric analysis using a thermogravimetric analyzer (TGA), at a temperature rise rate of 10° C./minute.

The first organic layer in the donor substrate of the present invention need not necessarily be formed of a single material, and may contain small amounts of other components, provided that the effect of the present invention is not impaired thereby. Essentially, the first organic layer may be formed of the organic material having the highest vaporization-starting temperature.

Provided that the above constituent elements are formed as essential constituent elements in the donor substrate of the present invention, the latter is not particularly limited as regards other constituent elements.

The second organic layer may be configured as a single layer formed of one type of organic material, but may be a multilayer film or a mixed film formed of a plurality of organic materials.

Examples of the organic layer in the donor substrate of the present invention having the above-described configuration include, for instance, a multilayer film, as represented by the second organic layer in which the vaporization-starting temperature of the layers increases from the side of the photothermal conversion layer towards the transfer surface. In such a configuration, the build-up of the donor substrate of the present invention can be easily achieved simply by overlaying a plurality of organic materials that form the donor layer in accordance with the vaporization-starting temperature of the organic materials. When producing a transfer film using the donor substrate of the present invention as described below, the effect of inhibiting the vaporization of other organic layers can be enhanced by way of the organic layer that is disposed on the side of the transfer surface.

In the donor substrate of the present invention, the photothermal conversion layer is ordinarily formed on the support substrate. The support substrate has preferably an insulating surface. Preferably, the support substrate can transmit irradiated radiation having a specific wavelength region.

In the donor substrate of the present invention, the photothermal conversion layer may be a metal plate doubling as a support substrate and having a thickness ranging from 10 to 200 μm. The support substrate can be omitted by using a metal plate containing a high-melting point metal. Costs can also be reduced as a result. Also, there is no need for a step of forming the photothermal conversion layer on the support substrate. The production process can be simplified accordingly.

If the metal plate is thinner than 10 μm, the metal plate fails to exhibit sufficient strength as a support substrate. If the thickness of the metal plate exceeds 200 μm, the thickness is excessive, and the function of the photothermal conversion layer is impaired. If the photothermal conversion layer is made up of a metal plate, therefore, the thickness of the latter ranges preferably from 10 to 200 μm.

In the present invention, the donor layer contain at least one selected from among an electroluminescent organic material, a hole-transporting organic material and an electron-transporting organic material. The foregoing materials may be incorporated singly or as plurality of combinations thereof.

Examples of the electroluminescent organic material, the hole-transporting organic material and of the electron-transporting organic material include, for instance, luminescent low-molecular materials, hole-transporting low-molecular materials and electron-transporting low-molecular materials. Specific examples include, for instance, 4,4′-bis[N-(1-naphthyl)-N-phenylamino]biphenyl (α-NPD), tris(8-quinolinolato) aluminum (III) (Alq), 4,4′-bis[N-(9,9-di(6)methylfluorene-2-yl)-N-phenylamino]biphenyl (DFLDPBi), bis(2-methyl-8-quinolinolato)(4-phenylphenolato) aluminum (III) (BAlq), LG101 (by LG Chemical), LG201 (by LG Chemical), TR-E314 (by Toray), NHT-5 (by Novaled), NET-5 (by Novaled), and the like; as well as aromatic dimethylidene compounds such as 4,4′-di(9-carbazolyl)biphenyl (CBP), 2-tert-butyl-9,10-di(2-naphthyl)anthracene (t-BuDNA), 9-[4-(9-carbazolyl)phenyl]-10-phenylanthracence (CzPA), 4,4′-bis(2,2′-diphenylvinyl)-biphenyl (DPVBi) or the like; oxadiazole compounds such as 5-methyl-2-[2-[4-(5-methyl-2-benzoxazolyl)phenyl]vinyl]benzoxazole or the like; triazole derivatives such as 3-(4-biphenylyl)-4-phenyl-5-t-butylphenyl-1,2,4-triazole (TAZ) or the like; styrylbenzene compounds such as 1,4-bis(2-methylstyryl)benzene or the like; fluorescent organic materials such as thiopyrazine dioxide derivatives, benzoquinone derivatives, naphthoquinone derivatives, anthraquinone derivatives, diphenoquinone derivatives, fluorenone derivatives or the like; an azomethine zinc complex or the like; phosphorescent compounds, specific examples of which include, for instance, (acetylacetonato)bis(2,3,5-triphenylpyrazinato) iridium (III) (Ir(tppr)2(acac)), bis[2-(4′,6′-difluorophenyl)pyridinato-N,C2′]iridium (III) picolinate (Flrpic), tris(2-phenylpyridinato-N,C2′) iridium (III) (Ir(ppy)3), bis(2-phenylpyridinato-N,C2′) iridium (III) acetylacetonato (Ir(ppy)2(acac)), bis(2-phenylbenzothiazolato-N,C2′) iridium (III) acetylacetonato (Ir(bt)2(acac)), tris(2-phenylquinolinato-N,C2′) iridium (III) (Ir(pq)₃), bis(2-phenylquinolinato-N,C2′) iridium (III) acetylacetonato (Ir(pq)2(acac)), bis(2-(2′-benzo[4,5-α]thienyl)pyridinato-N,C3′) iridium (III) acetylacetonato (Ir(btp)2(acac)), bis(1-phenylisoquinolinato-N,C2′) iridium (III) acetylacetonato (Ir(piq)2(acac)), (acetylacetonato)bis[2,3-bis(4-fluorophenyl)quinoxalinato]iridium (III) (Ir(Fdpq)2(acac)), and 2,3,7,8,12,13,17,18-octaethyl-21H,23H-porphyrin platinum(II) (PtOEP); and fluorescent compounds, specific examples of which include, for instance, perylene 2,5,8,11-tetra(tert-butyl)perylene (TBP), 4,4′-bis[2-(N-ethylcarbazole-3-yl) vinyl]biphenyl (BCzVBi), 5,12-diphenyltetracene, N,N′-dimethylquinacridone (DMQd), N,N′-diphenylquinacridone (DPQd), 4-dicyanomethylene-2-isopropyl-6-[2-(1,1,7,7-tetramethyljulolidine-9-yl)ethenyl]-4H-pyran (DCJTI), rubrene, coumarin 6, coumarin 30 and the like.

Luminescent materials, hole-transporting materials, and electron-transporting materials that are used in organic electroluminescent elements can be used as a luminescent material, a hole-transporting material and an electron-transporting material other than the-listed materials, which are not particularly limiting.

The donor layer may contain an n-type dopant material, in addition to the hole-transporting organic material. Examples of n-type dopant materials include, for instance, tetracyanoquinodimethane (TCNQ), tetrafluoro-tetracyanoquinodimethane (F₄-TCNQ), tetracyanonaphtho-quinodimethane (TNAP), and NDP-2 (by Novaled).

The donor layer may contain a p-type dopant material in addition to the electron-transporting organic material. Examples of p-type dopant material include, for instance, tetrathianaphthacene (TTN), tetrathiafulvalene (TTF), NDN-1 (by Novaled), NDN-26 (by Novaled) or the like.

Preferably, each donor layer is formed of an organic material whose vaporization-starting temperature ranges from 100° C. to 500° C. That is because in an organic material having a vaporization-starting temperature lower than 100° C., molecular weight is too small, and heat stability is poor in a thin film of the material; on the other hand, an organic material having a vaporization-starting temperature above 500° C. may thermally damage members that make up the donor substrate, such as the support substrate, partition, spacers and so forth.

The donor substrate may be further provided with a protective layer for protecting the photothermal conversion layer against oxidation, radiation and delamination caused by cleaning. The protective layer may be formed through formation, by CVD (Chemical Vapor Deposition), sputtering or the like, of a film of an inorganic material such as silicon oxide (SiOx) or silicon nitride (SiNx).

The present invention is also directed towards a process for production of a transfer film using a donor substrate configured as described above. Specifically, the present invention is also a process for production of a transfer film using the donor substrate, the process including: an arrangement step of arranging the donor substrate and the transfer receiving substrate opposite each other; and a film formation step of irradiating radiation onto the photothermal conversion layer of the donor substrate, to vaporize the organic materials that make up the donor layer and cause the organic materials to be deposited on a main surface of the transfer receiving substrate, and thereby forming a transfer film, wherein in the film formation step, both the organic material that forms the first organic layer and the organic material that forms the second organic layer are vaporized.

The above donor substrate is the donor substrate according to the present invention. In the arrangement step, the donor layer of the donor substrate and the transfer receiving substrate are arranged so as to oppose each other. The transfer receiving substrate is not particularly limited, but has preferably an insulating surface. As the transfer receiving substrate there can be widely employed various types of substrates, in accordance with the use thereof, for instance, a substrate formed of an inorganic material such as glass or quartz, a substrate formed of a plastic resin such as polyethylene terephthalate (PET), a substrate formed of a ceramic resin such as alumina, a substrate wherein a metal substrate of aluminum, iron and so forth is coated with an insulator such as SiO₂ or an organic insulating material, a substrate wherein the surface of a metal substrate is subjected to an insulating treatment by anodization or the like, or a substrate in which a substrate having circuits such as TFTs (thin film transistors) formed thereon is covered by an insulating material.

In the film formation step, the radiation irradiated onto the donor substrate need only be radiation that can be absorbed, and converted into heat, by the thermal conversion layer of the donor substrate. Specific examples include, for instance, laser beams, and lamps such as halogen lamps, flash lamps and the like.

In the film formation step, the radiation is converted into heat by the photothermal conversion layer, and the donor layer is heated by that heat. When the organic material that forms the donor layer vaporizes upon reaching the vaporization-starting temperature, the vaporized organic material becomes deposited on the main surface of the transfer receiving substrate, and the transfer film is formed as a result.

In the present invention, the organic material that forms the second organic layer is vaporized together with the organic material that forms the first organic layer. That is, the organic material that forms the first organic layer is formed of an organic material having a higher vaporization-starting temperature than that of the organic material that forms the second organic layer. In the heated donor layer, therefore, the organic material that forms the second organic layer is not transferred to the transfer receiving substrate, even upon reaching the vaporization-starting temperature, until the organic material that forms the first organic layer reaches its vaporization-starting temperature. Also, the second organic layer has already reached the vaporization-starting temperature by the time the first organic layer vaporizes upon reaching its vaporization-starting temperature. Therefore, the organic material that forms the first organic layer and the organic material that forms the second organic layer vaporize substantially simultaneously. As a result, the transfer film formed on the transfer receiving substrate in which a plurality of materials exhibits a substantially uniform composition distribution, not only in the surface direction of the film, but also in the perpendicular direction.

In a strict sense, the organic material that forms the first organic layer and the organic material that forms the second organic layer do not vaporize simultaneously, but do so with a small time lag in the respective vaporizations. However, the organic material having a low vaporization-starting temperature has a faster vaporization rate than the organic material having a high vaporization-starting temperature. Therefore, all the organic materials can reach the transfer surface of the transfer receiving substrate in a substantially uniformly dispersed state. This affords, as a result, a uniform composition distribution in the obtained transfer film.

Provided that the above steps are included as essential steps, the process for production of a transfer film according to the present invention is not particularly limited as regards other steps.

In the process for production of a transfer film, substantially the film thickness ratio of the organic layers that make up the donor layer and the volume mixing ratio of the organic materials in the transfer film are proportionally identical. Therefore, a transfer film having a desired material composition can be produced in an easy manner simply by controlling the film thickness of the organic layers that make up the transfer film.

The vaporization of the organic material that forms the second organic layer can be controlled yet more reliably by the first organic layer in the film formation step if the film thickness of the first organic layer becomes significantly greater than the film thickness of the second organic layer through adjustment of the film thickness of the organic layers, as described above.

In a case where, by virtue of the above configuration, the film thickness of the first organic layer becomes thinner than the film thickness of the second organic layer, the internal pressure in the second organic layer increases, on account of heating, before the organic material of the first organic layer reaches the vaporization-starting temperature, and thus the organic material of the first organic layer may also vaporize in some instances. In this case as well, however, all the organic materials vaporize substantially at the same time, as in the above-described case, and there can be formed a transfer film having a uniform material composition.

The above-described process for production of a transfer film according to the present invention can be used to produce various kinds of transfer film, but is suited for producing display elements, in particular for forming organic electroluminescent elements. Specifically, the present invention is also directed towards a process for production of an organic electroluminescent element using the process for production of a transfer film, wherein the transfer receiving substrate is a device substrate on which at least a first electrode is formed; the donor layer comprises at least one selected from among an electroluminescent organic material, a hole-transporting organic material and an electron-transporting organic material; in the film formation step, at least one layer selected from among an emissive layer, a hole-transport layer and an electron-transport layer is formed on the first electrode; and wherein the process further comprises an electrode formation step of forming a second electrode on the layer that is formed in the film formation step.

The organic electroluminescent element has a configuration wherein, as described above, an emissive layer or the like is disposed between a pair of electrodes, namely an anode and a cathode. To obtain an organic electroluminescent element having such a configuration, there is used a device substrate on which at least a first electrode is formed, and a thin film of an emissive layer or the like is formed, in accordance with the process for production of a transfer film, on the first electrode. The first electrode is a cathode in a case where the second electrode is an anode. If the second electrode is a cathode, the first electrode is an anode.

The first electrode and second electrode are patterned to a suitable shape depending on the driving scheme of the display device to be produced. For instance, if the driving scheme of the display device is a passive matrix scheme, the first electrode may be formed as stripes, and the second electrode may be formed as stripes that intersect the stripes of the stripe-like first electrode. In this case, the overlapping portions of the first electrode and the second electrode constitute the organic electroluminescent elements.

In a case where the driving scheme of the display device is an active matrix scheme in which a TFT is provided at each pixel, the first electrode is patterned conforming to each pixel in an array of a plurality of pixels, and the second electrode is formed in a state where the latter covers the transfer receiving substrate, so that the second electrode is used as a common electrode for the pixels. In this case as well, the overlapping portions of the first electrode and the second electrode constitute the organic electroluminescent elements. In an active matrix scheme, the first electrode and the second electrode may be connected to the TFTs that are provided in the pixels, or may be connected by way of contact holes that are formed in an interlayer dielectric that covers the TFTs.

The materials that form the first electrode and second electrode are selected depending on the light extraction method of the display device to be produced. In a case, for instance, where the display device is a top-emission display device in which light is extracted from the side, of the substrate on which a film is to be formed, that is opposite the side of a support substrate, the first electrode is formed of a high-reflection material, and the second electrode is formed of a light-transmitting material or semi-translucent material. If the display device is a dual-sided emission display device, the first electrode is formed of a transparent material, and the second electrode is formed of a light-transmitting material or semi-translucent material. If the display device is a bottom-emission display device in which light is extracted from the support substrate-side of the substrate on which a film is to be formed, the first electrode is formed of a light-transmitting material, and the second electrode is formed of a high-reflection material. The first electrode and the second electrode are formed, for instance by sputtering, using the above materials.

Specifically, if the display device is a top-emission display device and the first electrode is an anode, the first electrode is formed of a high-reflectance conductive material such as silver (Ag), aluminum (Al), chromium (Cr). iron (Fe), cobalt (Co), nickel (Ni), copper (Cu), tantalum (Ta), tungsten (W), platinum (Pt) or gold (Au), or out of alloys of the foregoing. Alternatively, the first electrode may have a stacked build-up in which a layer of the foregoing metals and alloys has formed thereon a layer comprising a metal having a high work function, such as gold (Au), platinum (Pt) or the like, or a high-transmittance conductive material such as a transparent conductive material, for instance, ITO (indium-tin-oxide), IZO (indium-zinc-oxide), IDIXO (indium oxide-indium zinc oxide; In₂O₃(ZnO)n), or SnO₂.

If the display device is a top emission display device and the first electrode is used as a cathode, the first electrode is built using a conductive material having a small work function. Examples of such conductive materials that can be used include, for instance, alloys of active metals such as lithium (Li), magnesium (Mg) or calcium (Ca) and metals such as Ag, Al, indium (In) or the like, or stacked structures of the foregoing. Between the first electrode and the organic layer 20 that is formed thereon there can be inserted a thin compound layer of, for instance, an active metal such as Li, Mg or Ca and oxygen or a halogen such as fluorine or bromine. The second electrode is formed of ITO, IZO or the like.

In a case where the display device is a transmissive or dual-sided emission display device and the first electrode is used as an anode, the first electrode can be formed of a transparent conductive material such as ITO, IZO, IDIXO, SnO₂ or the like.

Provided that the above steps are included as essential steps, the process for production of an organic electroluminescent element according to the present invention is not particularly limited as regards other steps.

In the present invention, preferably, the spacing between the donor substrate and the transfer receiving substrate in the film formation step is kept to as constant a spacing as possible, in order to obtain a transfer film having uniform film thickness. To achieve such a state, methods can be resorted to that involve, for instance, controlling the pressure of an atmosphere under which the film formation step is carried out, or using spacers, or mechanically holding the substrates. These methods may be used singly or in combination.

A method of controlling pressure may be, for instance, a method wherein, in the film formation step, the pressure in a space between the donor substrate and the transfer receiving substrate is lower than the pressure of an atmosphere under which the step is performed. As a result, the pressure outside the two substrates disposed opposing each other is higher than the pressure inside. The surface of the substrates becomes pressed in proportion to the resulting pressure difference. This allows maintaining a constant spacing between the substrates during film formation. Resorting to this method allows also lowering the vaporization-starting temperature of the organic material that makes up the organic layer of the donor substrate, and allows enhancing the production efficiency of the transfer film while suppressing material deterioration.

In a method of using spacers, the transfer receiving substrate may have a spacer at the outer edge of a region at which the transfer film is formed, so that, in the arrangement step, the transfer receiving substrate and the donor substrate are held, the spacer being in contact with the donor substrate. Thus, the spacing between the two substrates can be controlled in an easy manner by bringing the donor substrate and the transfer receiving substrate into contact via the spacer.

In a method that involves mechanically holding a substrate, the entirety of the substrates is pressed by mechanical means, or the two substrates are fixed to each other using a jig such as a clamping frame or the like.

In the present invention, preferably, the methods are used in combination. In particular, using a combination of a pressure control method and a method that relies on the use of spacers allows maintaining a constant spacing between the donor substrate and the transfer receiving substrate more reliably, and allows forming a transfer film having uniform film thickness.

Specifically, the film formation step may be carried out in a vacuum atmosphere, and the spacer may be provided with an opening for discharge of a gas between the transfer receiving substrate and the donor substrate. Such a method allows the gas present between the substrates that are arranged opposing each other in the arrangement step to be evacuated easily through an opening formed in the spacer.

The shape of the spacer is not particularly limited, and various shapes may be used. For instance, a columnar and/or stripe-like spacer can be used as the spacer.

Preferably, the spacer is provided at a non-pixel region, i.e. the outer edge of an emissive layer. As a result, there is no loss in the aperture ratio of the pixel region at which the emissive layer is formed, and an organic electroluminescent element is obtained that has high display characteristics.

As an example, the emissive layer may be rectangular, and the spacer may be formed at four corners in the outer edge of the emissive layer. Alternatively, the emissive layer may be rectangular and the spacer may be formed at the outer edge of the emissive layer, along four sides thereof.

When resorting to a combination of the above pressure control method and the use of a spacer the gas present between substrates can be evacuated in an easy manner if the stripe-like spacer is formed along a longitudinal direction or transversal direction of the transfer receiving substrate and the spacer is formed up to one end of the substrates.

In the present invention, the transfer receiving substrate further has, in addition to the spacer, an outer spacer that surrounds the spacer; such that at least part of the outer spacer may be formed non-contiguously. In such a configuration, gas between the substrates can be evacuated in an easy manner out of the non-contiguous portion that is formed in part of the outer spacer, in the same way as above.

The substrates can be held yet more stably if the arrangement shape of the outer spacer is symmetrical with respect to the longitudinal direction or the transversal direction of the substrate.

The arrangement shape of the outer spacer may be asymmetrical with respect to the longitudinal direction or the transversal direction of the substrate; and the transfer receiving substrate may further have a dummy spacer, such that a combination of the outer spacer and the dummy spacer is symmetrical with respect to the longitudinal direction or the transversal direction of the transfer receiving substrate. The two substrates can be held stably also by way of such a configuration.

Preferably, the spacer, outer spacer and dummy spacer are all formed of the same material, in terms of simplifying the production process. The material used for forming the spacers is not particularly limited, and may be a photosensitive resin or the like.

In the present invention, the transfer receiving substrate may have a partition that surrounds a region at which the transfer film is formed, such that, in the transfer film formation step, the transfer film is formed to a height reaching an end face of the partition on the donor substrate side. In such a configuration as well, the transfer film formation region is surrounded by the partition, the transfer receiving substrate and the donor substrate during film formation. Therefore, the vaporized material does not mix with materials of other pixel regions. This allows forming of a transfer film having uniform film thickness.

This feature is explained in detail next. The partition formed in the transfer receiving substrate is used not only in the transfer method according to the present invention, but also in vacuum evaporation methods and ink-jet methods. In vacuum evaporation methods, the partition is used for maintaining a constant distance between a substrate and a mask, and in ink-jet methods, the partition is used for demarcating pixels and prevent thereby the occurrence of mixed colors.

In the production process according to the present invention, the distance between the donor substrate and the transfer receiving substrate is very small, and the flying space of the material is enclosed by the partition, the transfer receiving substrate and the donor substrate. Therefore, the vaporized organic material has no directionality, but flies uniformly in a plane. A transfer film of uniform film thickness can be formed as a result on the transfer receiving substrate, and there can be eliminated leaks between the first electrode and the second electrode that arise from non-uniform film thickness. Even if the transfer film is formed to a height reaching an end face of the partition on the side of the donor substrate, there occurs no mixing with materials of other pixel regions, since the flying space of the material is demarcated for each pixel, as described above. This allows realizing an element having good luminous efficiency and excellent stability.

In vacuum evaporation methods, however, the distance between the transfer receiving substrate and a crucible, which is the material supply source, is significant. The flight properties of the material, having originally no directionality, are imparted as a result with directionality, and the film that is formed exhibits a smaller film thickness at the side faces of the partition, or may fail to be formed at all. Also, the film fails to be formed in the pixel to a uniform film thickness. In coating methods such as ink-jet methods, the ink material coated onto each pixel is affected, for instance, by surface tension. As a result, the film thickness becomes greater at the central portion of the pixels, and smaller at the side faces of the partition. The film fails thus to be formed to a uniform film thickness.

In vacuum evaporation methods and ink-jet methods, thus, a film cannot be formed up to a height that reaches the end face of a partition. Also, there appear portions at which no film is formed, or regions of small film thickness. This results in likelier occurrence of leaks between the first electrode and the second electrode, and gives rise to loss of luminous efficiency and formation of non-emitting pixels.

The aspects can be suitably combined with each other without departing from the scope of the present invention.

### EFFECT OF THE INVENTION

The donor substrate of the present invention, and the transfer method using the donor substrate, allow forming a transfer film having a uniform composition distribution, in an easy manner. The process for production of an organic electroluminescent element using the process for production of a transfer film allows realizing an organic electroluminescent element having good display characteristics.

### BRIEF DESCRIPTION OF THE DRAWINGS

FIG. 1 is a set of cross-sectional schematic diagrams illustrating the configuration of a donor substrate according to Embodiment 1;

FIG. 2 is a set of cross-sectional schematic diagrams illustrating various processes for producing the transfer film according to Embodiment 1;

FIG. 3 is a set of cross-sectional schematic diagrams for explaining a process for production of an organic electroluminescent element according to Embodiment 2;

FIG. 4 is a set of cross-sectional schematic diagrams for explaining a process for production of an organic electroluminescent element according to Embodiment 3;

FIG. 5 is a set of cross-sectional schematic diagrams for explaining a process for production of an organic electroluminescent element according to Embodiment 4;

FIG. 6 is a set of plan-view schematic diagrams illustrating the arrangement of the spacer, in a plan view of a transfer receiving substrate, according to Embodiment 5;

FIG. 7 is a plan-view schematic diagram illustrating the layout pattern of spacers, in a plan view of a transfer receiving substrate, according to Embodiment 6; and

FIG. 8 is a set of plan-view schematic diagrams for explaining a layout pattern of outer spacers and dummy spacers, in a plan view of a transfer receiving substrate, according to Embodiment 7.

### MODES FOR CARRYING OUT THE INVENTION

The present invention will be explained in more detail based on embodiments with reference to accompanying drawings. However, the present invention is not limited to these embodiments alone.

### Embodiment 1

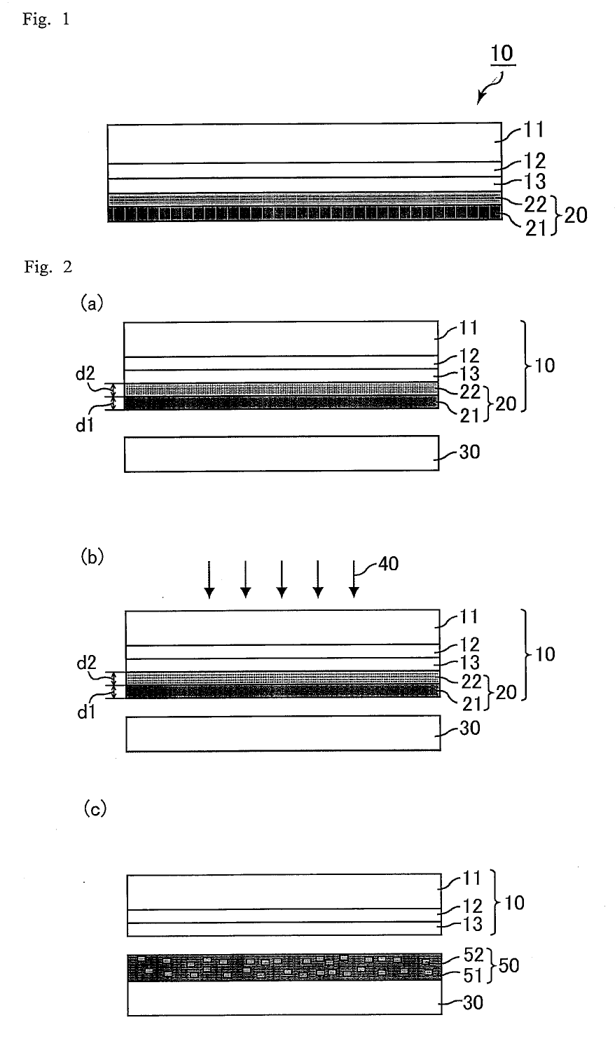

An explanation follows next, with reference to FIG. 1 and FIG. 2, on the donor substrate according to the present Embodiment 1 and on a process for production of a transfer film that uses the donor substrate. FIG. 1 is a cross-sectional schematic diagram illustrating the configuration of a donor substrate of the present embodiment, and FIG. 2 is a cross-sectional schematic diagram illustrating various processes for producing the transfer film.

In FIG. 1, a donor substrate 10 comprises a support substrate 11 and, on a main surface thereof, a photothermal conversion layer 12, a protective layer 13, and an organic layer 20 as a donor layer, in this order. The organic layer 20 has a two-layer structure including a first organic layer 21 and a second organic layer 22, such that the second organic layer 22 is made up of an organic material having a higher vaporization-starting temperature than that of the first organic layer 21.

The support substrate 11 has preferably an insulating surface. Preferably, the support substrate can transmit radiation of a specific wavelength region that is irradiated in a below-described transfer process. As the support substrate 11 having such a characteristic there can be used, for instance, a substrate formed of an inorganic material such as glass or quartz or the like, or a substrate formed of a plastic resin such as polyethylene terephthalate (PET) or the like.

Preferably, the photothermal conversion layer 12 is formed of a material that exhibits high efficiency in the conversion of radiation to heat (photothermal conversion efficiency) and having a high melting point. Specific examples thereof include, for instance, metals having a high melting point and low reflectance, such as titanium (Ti), molybdenum (Mo), chromium (Cr), or organic materials such as carbon black or organic pigments and dyes. The foregoing can be used singly or as mixtures of a plurality thereof.

If formed of the metal materials, the photothermal conversion layer 12 is formed by, for instance, sputter deposition, electron beam vapor deposition, resistance-heating vapor deposition or the like. If formed of the organic material, the photothermal conversion layer 12 is formed, for instance, by spin coating, dip coating, vacuum evaporation or the like. The thickness of the photothermal conversion layer 12 ranges preferably from 50 nm to 10 μm. Sufficient light absorption cannot be achieved if the thickness of the photothermal conversion layer 12 is smaller than 50 nm. On the other hand, a thickness of the photothermal conversion layer 12 greater than 10 μm is excessive and prevents the generated heat from being sufficiently transferred to the organic material. This impairs the operation of the photothermal conversion layer 12.

The protective layer 13 need only protect the photothermal conversion layer 12 against, for instance, oxidation, radiation and delamination caused by cleaning, and may be formed, for instance, out of an inorganic material such as silicon oxide (SiOx), silicon nitride (SiNx) or the like. The thickness of the protective layer 13 ranges preferably from 50 to 500 nm. The thickness of the protective layer 13 is not particularly limited, but is preferably not smaller than 50 nm, in order to sufficiently elicit the above-described protective effect on the photothermal conversion layer 12, and is preferably smaller than 500 nm, in order not to impair the heat generation effect of the photothermal conversion layer.

An example of the process for production of the donor substrate 10 having the configuration will be explained next. Firstly, the photothermal conversion layer 12 is formed, by sputter deposition or the like, on a main surface of the support substrate 11. Next, the protective layer 13 is formed, for instance by CVD, sputtering or the like, on the photothermal conversion layer 12. The second organic layer 22 is formed next on the protective layer 13, and the first organic layer 21 is formed then. The methods used for forming the abovementioned organic layers include, for instance, vacuum evaporation, and ordinary coating methods such as spin coating, bar coating, dip coating or the like, as well as various printing methods and transfer methods. The donor substrate 10 having the above-described configuration is obtained as a result.

An example has been explained above in which the photothermal conversion layer 12 is formed on the support substrate 11, but the present invention is not limited thereto in any way. For instance, there may be used a photothermal conversion layer 12 in the form of a metal plate that functions also as a support substrate, without any separate support substrate 11 being provided.

An explanation follows next, with reference to FIG. 2, on a process for production of a transfer film that uses the donor substrate 10 according to the present embodiment. FIG. 2(a) is a cross-sectional schematic diagram illustrating a step of arranging the donor substrate 10 with respect to a transfer receiving substrate. FIG. 2(b) is a cross-sectional schematic diagram for explaining a film formation step.

Firstly, as illustrated in FIG. 2(a) the organic layer 20 of the donor substrate 10 and the transfer receiving substrate 30 are disposed so as to oppose each other.

The transfer receiving substrate 30 has preferably an insulating surface. As the transfer receiving substrate 30 there can be widely used, for instance, a substrate formed of an inorganic material such as glass or quartz, a substrate formed of a plastic resin such as PET, a substrate formed of a ceramic resin such as alumina, a substrate wherein a metal substrate of aluminum or iron is coated with an insulator such as SiO₂ or an organic insulating material, a substrate wherein the surface of a metal substrate is subjected to an insulating treatment by anodization or the like, or a substrate in which the surface of a substrate having circuits such as TFTs formed thereon is covered by an insulating film.

Next, radiation 40 is irradiated from the side of the donor substrate 10, as illustrated in FIG. 2(b). As the radiation 40 there can be used, for instance, laser beams or lamp light from a halogen lamp, a flash lamp or the like.

Upon irradiation of radiation 40, the latter is absorbed by the photothermal conversion layer 12, and is converted to heat by which the organic layer 20 is heated. In the present embodiment, therefore, the first organic layer 21 formed of an organic material having a high vaporization-starting temperature is disposed on the side of the transfer surface. Therefore, even if the second organic layer 22 reaches the vaporization-starting temperature on account of the heat generated by the photothermal conversion layer 12, the organic material that forms the second organic layer 22 cannot vaporize since the second organic layer 22 is covered by the first organic layer 21 that is in a solid state.

The organic material that forms the first organic layer 21 vaporizes, and is transferred to the transfer receiving substrate 30 when the first organic layer 21 reaches the vaporization-starting temperature through further rise in the temperature of the photothermal conversion layer 12, on account of the irradiated radiation 40. At this time, the organic material that forms the second organic layer 22 having already reached the vaporization-starting temperature vaporizes out of vaporizable sites, and is transferred, simultaneously with the advance of vaporization of the organic material that forms first organic layer 21, under conditions of strong radiation intensity and abrupt rise in temperature.

There is some discrepancy between the times at which there begin the vaporizations of the organic material that forms the first organic layer 21 and of the organic material that forms the second organic layer 22. Ordinarily, however, a lower vaporization-starting temperature of an organic material entails a greater vaporization rate and faster transfer onto the transfer receiving substrate 30. As a result, the material vaporized out of the first organic layer 21 and the material vaporized out of the second organic layer 22 become deposited substantially uniformly on the transfer-receiving surface of the transfer receiving substrate 30.

FIG. 2(c) is a cross-sectional schematic diagram illustrating the state of each substrate after the film formation step. The organic layer 20 formed on the donor substrate 10 vaporizes completely, and disappears. A transfer film 50 becomes formed on the main surface of the transfer receiving substrate 30. In the transfer film 50, a material 52 resulting from the vaporization of the second organic layer 22 and a material 51 resulting from the vaporization of the first organic layer 21 are dispersed substantially uniformly not only in the surface direction of the film but also in the perpendicular direction thereof. In the present embodiment, thus, a transfer film having a uniform material composition can be formed in an easy manner even if the transfer film is formed using a plurality of organic materials.

The volume mixing ratio of the material 51 and the material 52 is identical to that of the ratio between the film thickness d1 of the first organic layer 21 and the film thickness d2 of the second organic layer 22. In the present embodiment, thus, the film thickness ratio of each organic layer is substantially identical to that of the volume ratio of the materials of the transfer film 50. Therefore, the film thickness ratio of the donor layer may be set in accordance with the volume mixing ratio of the materials that make up the desired transfer film 50.

### Embodiment 2

In the present embodiment there is explained a specific example of a process for production of an organic electroluminescent element using the process for production of a transfer film according to Embodiment 1. Features identical to those of Embodiment 1 are denoted with the same reference numerals and a recurrent explanation thereof will be omitted.

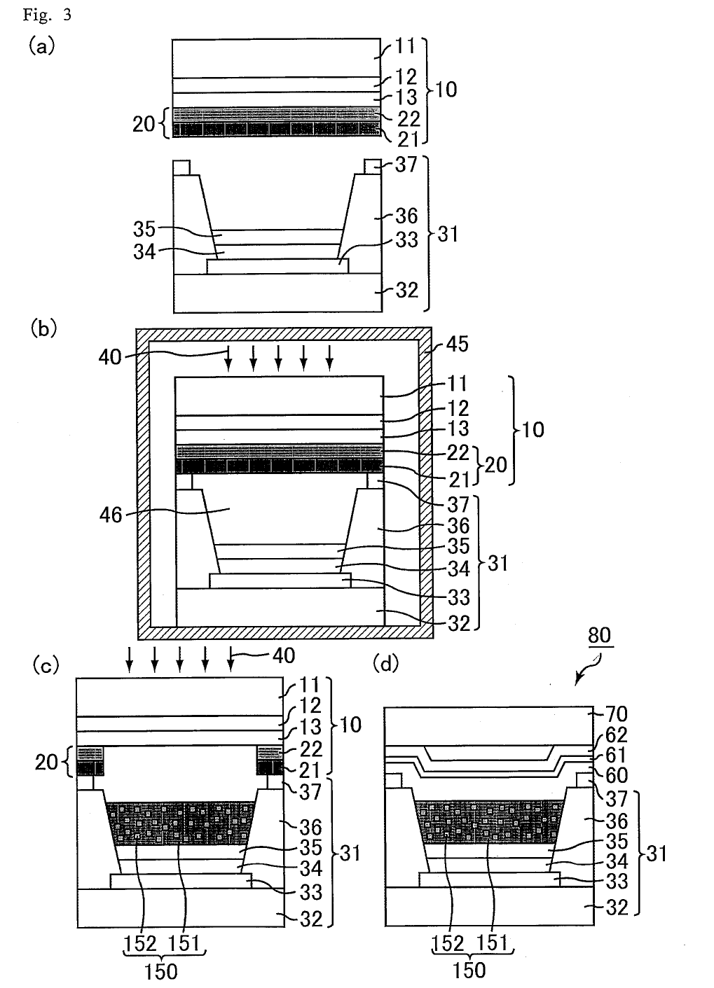

FIG. 3 is a cross-sectional schematic diagram for explaining a process for production of an organic electroluminescent element according to the present embodiment. FIG. 3(a) is a cross-sectional schematic diagram illustrating the donor substrate 10 and the transfer receiving substrate 31 used in the present embodiment.

In FIG. 3(a), the configuration of the donor substrate 10 was identical to that in Embodiment 1, but herein, the support substrate 11 was a 0.7 mm-thick glass substrate, the photothermal conversion layer 12 was a 100 nm-thick titanium film, and the protective layer 13 was a 100 nm-thick SiNx film.

In the organic layer 20, the first organic layer 21 was made up of a red emissive layer host material having a vaporization-starting temperature of 270° C., and the second organic layer 22 was of a red luminescent guest material having a vaporization-starting temperature of 235° C. In the formed transfer film, the film thickness of the first organic layer 21 was set to 29.1 nm and the film thickness of the second organic layer 22 was set to 0.9 nm, so as to yield a mixing ratio, on volume ratio basis, of 97:3 between the red emissive layer host material and the red luminescent guest material.

An example of the process for production of the donor substrate 10 is explained next. Firstly, a photothermal conversion layer 12 is formed on a 0.7 mm-thick glass substrate, as the support substrate 11, through formation of a 100 nm-thick titanium film by sputter deposition.

Next, a 100 nm-thick SiNx film is formed, by sputter deposition, on the photothermal conversion layer 12, to form thereby the protective layer 13. The organic layer 20 is formed through sequential formation of the second organic layer 22 and the first organic layer 21, by vacuum evaporation, on the protective layer 13, to yield the donor substrate 10 having the above-described configuration.

The transfer receiving substrate 31 is a substrate for forming an organic electroluminescent element. Therefore, unlike in Embodiment 1, a first electrode (anode) 33, a hole-injection layer 34, and a hole-transport layer 35 are stacked, in this order, on the main surface of a support substrate 32. Also, a partition (edge cover) 36 is formed so as to surround the transfer film formation region, and there are provided spacers 37 that are formed on the partition 36.

An example of the process for production of the transfer receiving substrate 31 having the above configuration is explained next. Firstly, an ITO electrode patterned to a desired shape and size is formed, by photolithography, on a 0.7 mm-thick glass substrate, as the support substrate 32, to yield the first electrode 33.

Next, there is formed a partition 36 that surrounds the transfer film formation region, and there are formed the spacers 37 on the partition 36, through patterning by photolithography or the like, using an acrylic resin. As a result, the opening surrounded by the partition 36 yields a pixel region at which there is provided a respective organic electroluminescent element.

The surface of the obtained first electrode 33 is cleaned next. The cleaning method may involve, for instance, performing ultrasonic cleaning for 10 minutes using acetone, isopropyl alcohol (IPA) or the like, followed by ultraviolet (UV)-ozone cleaning for 30 minutes.

Next, the hole-injection layer 34 is formed so as to cover the cleaned first electrode 33. The hole-injection layer 34 is formed through vapor deposition to a film thickness of several tens of nm, for instance by vacuum evaporation, using an ordinary positive hole injection material such as CuPc (copper phthalocyanine), polyaniline (PANI), (3,4-poly-ethylenedioxythiophene)/poly(styrene sulfonate)(PEDOT/PSS), m-MTDATA [4,4,4-tris(3-methylphenylphenylamino)triphenylamine]; LG101 (by LG Chem) or the like. Herein, the hole-injection layer 34 was formed of a film comprising LG101, to a film thickness of 10 nm, by vacuum evaporation.

The hole-transport layer 35 is formed next so as to cover the obtained hole-injection layer 34. The hole-transport layer 35 is formed by vapor deposition to a film thickness of several tens of nm, for instance by vacuum evaporation, using ordinary hole-transporting materials. Specific examples of the latter include, for instance, aromatic tertiary amine compounds such as N,N′-bis-(3-methylphenyl)-N,N′-bis-(phenyl)-benzidine (TPD), N,N′-di(naphthalene-1-yl)-N,N′-diphenyl-benzidine (α-NPD) or the like; low-molecular materials such as porphyrin compounds, hydrazone compounds, quinacridone compounds, styrylamine compounds and the like; polymeric materials such as poly[triphenylamine derivative] (Poly-TPD), polyvinyl carbazole (PVCz) or the like; and polymeric material precursors such as poly (p-phenylenevinylene) precursor (Pre-PPV), poly (p-naphthalenevinylene) precursor (Pre-PNV) or the like; as well as inorganic p-type semiconductor materials. Herein, the hole-transport layer 35 was formed of a film comprising α-NPD, to a film thickness of 30 nm, by vacuum evaporation. The transfer receiving substrate 31 was obtained as a result.

An emissive layer, as a transfer film, is formed as a result of a substrate arrangement step and a film formation step identical to those of the Embodiment 1, using the donor substrate 10 and the transfer receiving substrate 31 configured as described above. In the present embodiment, however, the substrate arrangement step and the film formation step are performed in a vacuum chamber in order to form a transfer film (emissive layer) having a yet more uniform film thickness.

Firstly, as illustrated in FIG. 3(b), the donor substrate 10 and the transfer receiving substrate 31 are conveyed into a vacuum chamber 45, and the two substrates are brought into contact with each other across spacers 37. This allows keeping a constant spacing between the donor substrate 10 and the transfer receiving substrate 31, and allows demarcating, by means of the partition 36, the transfer film formation region. The space 46 between the donor substrate 10 and the transfer receiving substrate 31 is a closed space. However, the size of the space 46 can be adjusted on the basis of the thickness of the spacers 37. The space 46 is formed so as to correspond to a respective pixel.

The thickness of the spacers 37 is not particularly limited, but ranges preferably from about 0.5 to 20 μm, terms of the size of, for instance, the space 46 and the stability of the donor substrate 10 to be supported. The spacers 37 cannot fully function as such if the thickness thereof is smaller than 0.5 μm. A thickness of the spacers 37 greater than 20 μm makes it more difficult to support the donor substrate 10 stably. Also, a greater space 46 makes it more difficult for the organic material that is vaporized during film formation to be transferred uniformly onto the surface of the transfer receiving substrate 31.

In addition to holding of the donor substrate 10 by way of the spacers 37, in the present embodiment there is used a method of controlling the pressure of the atmosphere under which the film formation step is carried out, in such a way so as obtain a transfer film having a yet more uniform film thickness in the subsequent film formation step. That is, the pressure in the space 46 may be identical to atmospheric pressure, but, preferably, the space 46 is evacuated to a pressure lower than the pressure of the atmosphere under which the film formation step is carried out. The two substrates are pressed more uniformly as a result.

Specifically, the pressure Pa in the vacuum chamber 45 is first adjusted to a degree of vacuum of about 1×10⁻³ Pa. Evacuation from atmospheric pressure down to about 1 Pa is preferably performed using an oil-free pump. For higher vacuum, evacuation to a range of about 5×10⁻⁵ Pa is preferably carried out using, for instance, a magnetic levitation-type turbomolecular pump, a compound molecular pump, a cryo-pump or the like. In this case, the pressure Pb of the space 46 was set to about 1×10⁻³ Pa. The substrate, in that state, is fixed through clamping using a clamping frame (not shown).

Next, the interior of the vacuum chamber 45 is slowly leaked, by means of an inert gas or the like, to lower the degree of vacuum, whereupon the pressure Pa in the vacuum chamber 45 becomes higher than the pressure Pb in the space 46, so that there holds the relationship Pa>Pb. As a result, the donor substrate 10 becomes pressed in proportion to the difference in pressure. The two substrates thus fit closely to each other, which allows keeping a constant distance between the substrates. Pressing performed on the basis of such pressure difference is very uniform. This configuration allows keeping a constant distance between the substrates all over the pixels and, and allows forming a uniform film in a below-described film formation step.

The radiation 40 is irradiated onto the donor substrate 10 arranged as described above. As the radiation 40 there was irradiated laser light having a wavelength of 808 nm using a CW laser diode (Hamamatsu Photonics, L9399).

The space 46 is evacuated as described above upon irradiation of the radiation 40 according to the present embodiment. The vaporization-starting temperature of the organic material drops accordingly, and the transfer film can be formed through irradiation of a lower energy, while it becomes possible to prevent deterioration or negative thermal effects on the organic materials.

Irradiation of laser light is accomplished, for instance, by spot-irradiation of a laser beam over the width of a pixel, accompanied by scanning of the spot, or by using a light-shielding film that restricts the region irradiated by the laser beam. It becomes possible thereby to form a transfer film only at desired pixels, in an easy manner.

As a result of the abovementioned laser beam irradiation, the photothermal conversion layer 12 absorbs the laser beam, and converts the latter into heat whereby the organic layer 20 is heated. In the same way as in Embodiment 1, the organic material that forms the first organic layer 21 on the side of the transfer surface reaches then the vaporization-starting temperature, and the organic material that forms the second organic layer 22 vaporizes as well.

In the present embodiment, the film thickness of the second organic layer 22 is of 0.9 nm, as described above, whereas the film thickness of the first organic layer 21 is sufficiently large, of 29.1 nm. Therefore, the vaporization of the organic material that makes up the second organic layer 22 can be sufficiently controlled by the vaporization-starting temperature of the organic material that makes up the first organic layer 21.

As illustrated in FIG. 3(c), the portion of the first organic layer 21 and the second organic layer 22 of the donor substrate 10 that is irradiated by the radiation 40 is vaporized and disappears. In the same way as in Embodiment 1, a material 151 vaporized out of the first organic layer 21 and a material 152 vaporized out of the second organic layer 22 are deposited, substantially uniformly, onto the transfer surface of the transfer receiving substrate 31, on the hole-transport layer 35 of the transfer receiving substrate 31, to form thereby the transfer film 150.

As described above, the material 151 vaporized out of the first organic layer 21 and the material 152 vaporized out of the second organic layer 22 are dispersed substantially uniformly in the transfer film 150. The volume mixing ratio of the material 151 and of the material 152 is identical to the film thickness ratio of the first organic layer 21 and the second organic layer 22.

FIG. 3(d) is a cross-sectional schematic diagram illustrating the configuration of an organic electroluminescent element 80 obtained using the transfer receiving substrate 31 having the transfer film 150 formed thereon. The donor substrate 10 is removed from the transfer receiving substrate 31, and there is formed an electron-transport layer 60 that covers the entire substrate, including the transfer film 150.

The electron-transport layer 60 is formed of an ordinary electron-transport material. Herein the electron-transport layer 60 was formed to a film thickness of 60 nm by vacuum evaporation, using Alq. A positive hole barrier layer for enhancing carrier balance may be formed between the transfer film 150 and the electron-transport layer 60.

An electron injection layer 61 that covers the electron-transport layer 60 is formed next. The electron injection layer 61 is formed of an ordinary electron injection material. Herein the electron injection layer 61 was formed to a film thickness of 1 nm by vacuum evaporation, using lithium fluoride (LiF).

A second electrode (cathode) 62 that covers the electron injection layer 61 was formed next. Herein, the second electrode 62 was formed to a film thickness of 100 nm by vacuum evaporation, using Al.

A sealing glass substrate 70 was then bonded to the whole, using a UV (ultraviolet)-curable resin, to yield the organic electroluminescent element 80 according to the present embodiment.

The material 151 and the material 152 were uniformly dispersed, in the transfer film 150 that constitutes the emissive layer, in the obtained organic electroluminescent element 80, both in the film surface direction and the perpendicular direction. The element exhibited excellent display characteristics as a result. Hereafter, the organic electroluminescent element 80 will also be referred to as element A.

In the above explanation, an example has been described wherein, in the film formation step, a constant substrate spacing system is maintained by way of the spacers 37 and by a pressure difference. However, the present invention is not limited thereto, and the spacing may be maintained by relying on mechanical forces. In pressing methods that rely on pressure differences, as described above, air paths may fail to be secured during evacuation, and uneven internal pressure may occur, if the shape of the spacers disposed between the substrates is complex, in particular if spacers are arrayed in a complex layout. In such cases, the distance between substrates can be kept constant, and uniform pressing can be carried out, by holding the substrates mechanically.

Examples of pressing methods that rely on mechanical forces include, for instance, methods in which a platen for pressing is disposed in a chamber, and there is provided a shock-absorbing ring that controls the spacing between the platen and the chamber, so that the platen exerts pressure through control of the spacing according to the degree of vacuum. In other methods, pressing may conceivably be accomplished by shifting the position of the platen itself. The pressing method is thus not particularly limited.

In the above explanation, the first electrode 33 comprises an ITO electrode, but the present invention is not limited thereto.

In the above explanation, the surface of the transfer film 150 is at a position lower than the height of a side wall 36, but the surface of the transfer film 150 may stand at a position substantially identical to the height of the side wall 36. In such a configuration as well, the space 46 is a closed space in the film formation step illustrated in FIG. 3(b), and hence there is no mixing with materials of the transfer film formed at other pixel regions.

### Comparative Embodiment 1

For purposes of comparison with the element A of Embodiment 2, an organic electroluminescent element was manufactured using a donor substrate having a different configuration of the organic layer 20 of the donor substrate 10. Specifically, the organic layer did not have a two-layer structure such as the above-described one. Instead, both layers were mixed and there was formed a mixed film by co-evaporation. Otherwise, the organic electroluminescent element was produced in the same way as in Embodiment 2. The obtained organic electroluminescent element is referred to as element B.

### Comparative Embodiment 2

For purposes of comparison with the element A produced in Embodiment 2, an organic electroluminescent element was produced not by transfer using a donor substrate, but by vacuum evaporation. Specifically, an emissive layer was formed, by co-evaporation, on the hole-transport layer 35 of the transfer receiving substrate 31, using an organic material identical to that of the organic material that makes up the organic layer 20 of the donor substrate 10. Otherwise, the organic electroluminescent element was produced in the same way as in Embodiment 2. The obtained organic electroluminescent element is referred to as element C.

Characteristic Comparison

Various characteristics of element A according to Embodiment 2, element B according to Comparative embodiment 1 and element C according to Comparative embodiment 2 were assessed. Elements A to C exhibited all red emission. It was found that the current efficiency (cd/A) of element A was comparable to the current efficiency of element C, while the current efficiency of the foregoing two was about 45% higher than the current efficiency of element B. This showed that luminous efficiency increased through the use of the configuration of the present embodiment, if the emissive layer is formed by a transfer method.

The emissive layers of elements A to C were subjected to TOF-SIMS (time-of-flight secondary ion mass spectrometry). It was found that the two materials 151, 152 were uniformly mixed in element A and element C, whereas element B exhibited variation in the composition distribution of the materials 151, 152 in the film thickness direction.

The above suggests that the reason for the high current efficiency of element A and element C is attributable to the uniform composition distribution of the materials 151, 152 that make up the emissive layer, as a result of which the positive holes or electrons injected from the hole-transport layer or the electron-transport layer are transported with good efficiency, and carrier balance is good, all of which makes for efficient emission.

### Embodiment 3

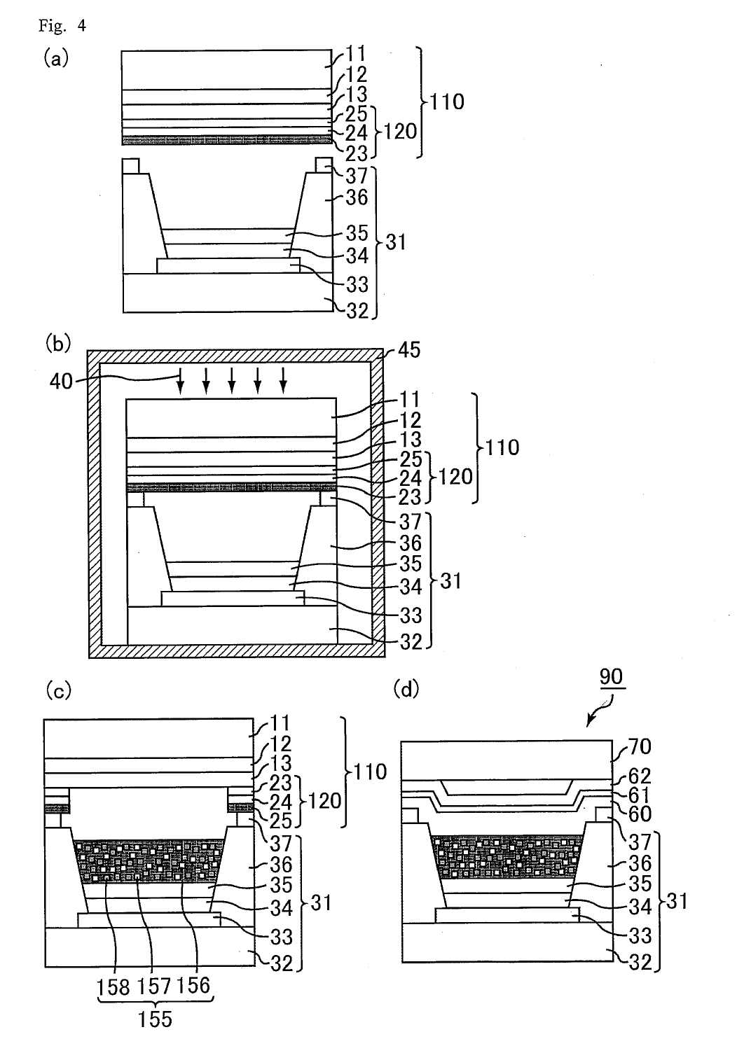

In the present embodiment there is manufactured a transfer film using a donor substrate in which the second organic layer is a multilayer film; specifically, the organic layer has a three-layer structure. Other features are identical to those of Embodiment 2. FIG. 4 is a cross-sectional schematic diagram for explaining a process for production of an organic electroluminescent element according to the present embodiment.

In FIG. 4(a), a donor substrate 110 has the support substrate 11, the photothermal conversion layer 12 and the protective layer 13, configured in the same way as in Embodiment 2. On the protective layer 13 there is formed an organic layer 120 having a three-layer structure. The organic layer 120 comprises a first organic layer 23 disposed on the side of the transfer surface, and a second organic layer having a two-layer structure. The second organic layer is made up of organic layers 24, 25.

Specifically, the organic layer 120 comprises the first organic layer 23 formed of a red emissive layer host material, the organic layer 24 formed of a red emissive layer stabilizing dopant material, and an organic layer 25 formed of a red luminescent guest material. The materials that form each organic layer have descending vaporization-starting temperatures in the order first organic layer 23 and organic layers 24, 25 that make up the second organic layer.

As regards the film thickness of the various organic layers, the film thickness of first organic layer 23 was set to 26.1 nm, the film thickness of the organic layer 24 was set to 3 nm, and the film thickness of the organic layer 25 was set to 0.9 nm, in such a manner that the mixing ratio of the material 156 resulting from the transfer of the red emissive layer host material, the material 157 resulting from the transfer of the red emissive layer stabilizing dopant material and the material 158 resulting from the transfer of the red luminescent guest material was material 156:material 157:material 158=87:10:3 in the emissive layer to be formed. The various organic layers were formed by vacuum evaporation.

The two substrates were disposed opposing each other in the vacuum chamber 45, as illustrated in FIG. 4(b), using the transfer receiving substrate 31 having the same configuration as in Embodiment 2. The same process as in FIG. 3(b) was carried out through irradiation of radiation 40. As a result there was formed the transfer film 155 that constitutes an emissive layer on the transfer receiving substrate 31, as illustrated in FIG. 4(c). The materials 156 to 158 were uniformly dispersed in the transfer film 155.

Otherwise, an organic electroluminescent element 90 was produced in the same way as in Embodiment 2. Hereafter, the organic electroluminescent element 90 will also be referred to as element D.

### Comparative Embodiment 3

For purposes of comparison with the element D of Embodiment 3, an organic electroluminescent element was manufactured using a donor substrate having a different configuration of the organic layer 120. Specifically, the organic layer of the donor substrate was not a three-layer structure but a mixed film formed through co-evaporation of a mixture of all the materials. Otherwise, the organic electroluminescent element was produced in the same way as in Embodiment 3. The obtained organic electroluminescent element is referred to as element E.

### Comparative Embodiment 4

For purposes of comparison with the element D produced in Embodiment 3, an organic electroluminescent element was produced not by transfer using a donor substrate, but by vacuum evaporation. Specifically, a transfer film was formed, by co-evaporation, on the hole-transport layer 35 of the transfer receiving substrate 31, using an organic material identical to that of the organic material that makes up the organic layer 120 of the donor substrate 110. Otherwise, the organic electroluminescent element was produced in the same way as in Embodiment 3. The obtained organic electroluminescent element is referred to as element F.

Characteristic Comparison

Various characteristics of element D according to Embodiment 3, element E according to comparative embodiment 3 and element F according to comparative embodiment 4 were assessed. Elements D to F exhibited all red emission. It was found that the current efficiency (cd/A) of element D was comparable to the current efficiency of element F, while the current efficiency of the foregoing two was about 38% higher than the current efficiency of element E. This showed that luminous efficiency increased through the use of the configuration of the present embodiment, if the emissive layer is formed by a transfer method.

The emissive layers of the elements D to F were subjected to TOF-SIMS (time-of-flight secondary ion mass spectrometry). It was found that the three materials 156, 157, 158 were uniformly mixed in element D and element F, whereas element E exhibited variation in the composition distribution of the materials 156, 157, 158 in the film thickness direction.

The above suggests that the reason for the high current efficiency of element D and element F is attributable to the uniform composition distribution of the materials that make up the emissive layer, whereby the positive holes or electrons injected from the hole-transport layer or the electron-transport layer are transported with good efficiency. Carrier balance is good and emission efficient as a result.

### Embodiment 4

The present embodiment differs from Embodiment 2 in that herein the donor substrate used is a donor substrate in which the photothermal conversion layer is a metal plate having a thickness ranging from 10 to 200 μm and that functions also as a support substrate, other features being identical to those of Embodiment 2.

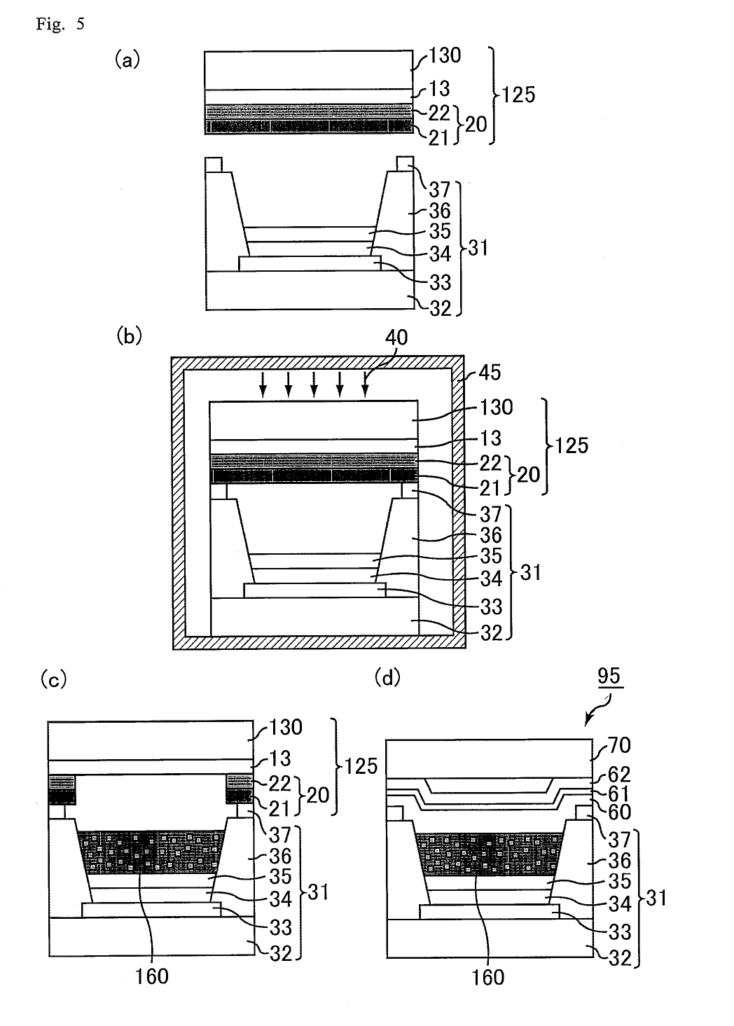

As illustrated in FIG. 5(a), the donor substrate 125 according to the present embodiment has a photothermal conversion layer 130 that doubles as a support substrate. A 100 μm-thick titanium plate was used as the photothermal conversion layer 130.

As illustrated in FIG. 5(b), the donor substrate 125 having the above configuration and the transfer receiving substrate 31 were disposed opposing each other inside the vacuum chamber 45, in the same way as in Embodiment 2, and radiation 40 was irradiated. A transfer film 160 was obtained as a result, as illustrated in FIG. 5(c), and an organic electroluminescent element 95 illustrated in FIG. 5(d) was then obtained in the same way as in Embodiment 2.

The above configuration afforded an element having good display characteristics, as those of element A according to Embodiment 2. The donor substrate 125 did not employ a glass substrate as the support substrate, and hence manufacturing processes and costs could be successfully reduced.

### Embodiment 5

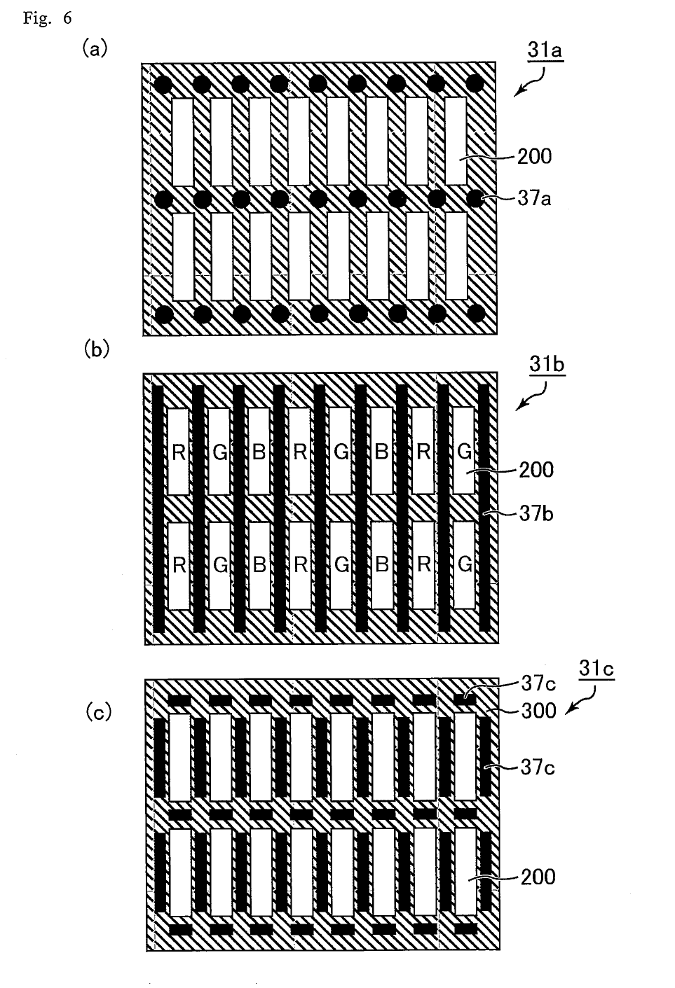

An explanation follows next, with reference to FIG. 6, on an example of the layout pattern of the spacers 37 according to Embodiment 2. FIGS. 6(a) to (c) are plan-view schematic diagrams illustrating the arrangement of the spacers, in a plan view of the transfer receiving substrate.

In FIG. 6(a) to (c), rectangular pixels 200 are disposed on transfer receiving substrates 31a to 31c, such that various spacers 37a to 37c are disposed around the pixels 200. The spacers 37a to 37c are preferably disposed in a number and over an area that are both as small as possible while enabling a constant spacing to be maintained between the donor substrate 10 and the transfer receiving substrates 31a to 31c. Preferably, the spacers 37a to 37c are formed uniformly within the plane of the substrates.

FIG. 6(a) illustrates an example wherein columnar spacers 37a are disposed around respective pixels 200. Such a configuration allows reducing the surface area over which the spacers 37a are disposed. In turn, this allows reducing the influence of positional offset between the donor substrate 10 and the transfer receiving substrates 31a to 31c.

FIG. 6(b) illustrates an example in which stripe-like spacers 37b are disposed between pixels 200. Such a layout pattern of the spacers 37b is particularly appropriate for cases where the pixels 200 are a color array of red (R), green (G) and blue (B).

In a case where an RGB color display element is formed, specifically, the pixels are disposed as stripes for each respective RGB color. In such cases, it is important that a transfer film having a uniform material composition and uniform film thickness be formed in one pixel during formation of the transfer film by a method according to the above embodiments. However, all the pixels in each column partitioned by the spacers 37b, i.e. all the pixels of a same color disposed in the same column, must have a uniform material composition and uniform film thickness. That is because the film-forming materials and optimal values of film thickness are dissimilar for the respective RGB colors.

In the present embodiment, as illustrated in FIG. 6(b), there are disposed stripe-like spacers 37b. During film formation, the vaporized organic material flies into the regions demarcated by the spacers 37b, to form a film on the transfer receiving substrate 31b. As a result, pixels of a same color and disposed in a same column exhibit all a uniform material composition and uniform film thickness. Moreover, film formation can take place without mixing with the materials that are transferred onto pixels of dissimilar colors.

FIG. 6(c) is an example in which spacers 37c are disposed so as to surround each pixel 200 and gaps 300 are provided at regions corresponding to the corners of the pixels 200. Such a layout pattern of the spacers 37c is preferable in a case where the film formation step is performed in a vacuum chamber, since air can be evacuated between the substrates via the gaps 300. The above does not apply to a case where bonding and separation of substrates is performed in vacuum.

In the above explanation, the spacers 37a in FIG. 6(a) are disposed at the four corners of each pixel 200, but the present invention is not limited to that layout pattern, and the number of spacers 37a can be reduced or increased. Also, the spacers 37a have been exemplified as cylindrical spacers 37a, but the present invention is not limited thereto, and the shape of the spacers is not particularly limited; for instance, the spacers may be square or polygonal prisms.

In FIG. 6(b) an example has been explained in which the RGB pixels are disposed in respective stripes, but the RGB pixels may be disposed as a delta array. In this case, preferably, the spacers are disposed on the four sides the pixels, and are arrayed in such a manner that a gap is formed in at least one of the four spacers.

In FIG. 6(c), gaps 300 are provided at the four corners of each pixel 200, but the present invention is not limited thereto, and the gaps 300 need only be provided at least at part of the periphery of the pixels 200.

The above explanation dealt with an example of the spacers 37 of the transfer receiving substrate 31 according to Embodiment 2, but the present invention is not limited thereto, and the explanation applies also to the transfer receiving substrate 31 according to Embodiment 3 as well as to transfer receiving substrates according to the present invention having other configurations.

### Embodiment 6

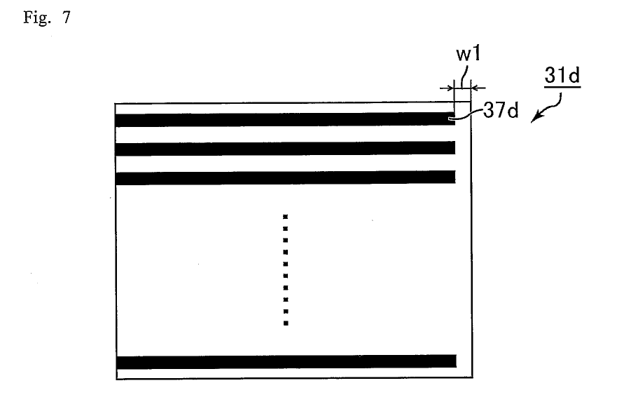

An explanation follows next on a spacer layout pattern of the present embodiment that is different from that of Embodiment 5 above. FIG. 7 is a plan-view schematic diagram illustrating a spacer layout pattern according to the present embodiment. In FIG. 7, the spacers 37d formed on a transfer receiving substrate 31d are formed as stripes from one end to the other end of the transfer receiving substrate 31d, so that one of the ends is opened in such a manner that there is a continuous space between the substrates over the entire region at which the substrates are bonded to each other.

In a case where the spacers 37d are not formed up to the end of the transfer receiving substrate 31d, the distance between substrates may become narrower at the end of the substrates during evacuation, or, alternatively, the opening may disappear in that the substrates come into contact with each other. As a result, gas may fail to be thoroughly evacuated between the substrates, so that a film of the material may fail to be formed uniformly. As described above, however, forming the spacers up to the end on at least one side of the substrate allows preserving the distance between substrates also at one end of the substrates, and enables uniform evacuation of the gas (air) between the substrates during the vacuum process.

More preferably, the spacers are formed up to the end of the substrates, but need not be so formed, as long as an opening between substrates is preserved at the end of the substrates. The width w1 in FIG. 7 is preferably as narrow as possible. Specifically, the width is preferably no greater than 1 mm.

Preferably, the spaces between the substrates are continuously connected, from the opening portions at the ends of the substrates up to all the pixel regions. In the case of stripe-like spacers, for instance, the spacers are formed from at least one opening up to the end of the farthest pixel. As a result, evacuation can be performed uniformly from the openings up to the farthest pixel, which in turn enables uniform film formation. The spacers formed up to the end of the substrate need only be formed along at least one side of the substrate. However, the formation site of the spacers is not limited, and the spacers may also be formed along other sides.

In the above explanation, the formation site of the region at which the spacers are not formed is not particularly limited. Likewise, the number and so forth of the spacers 37d is not particularly limited.

### Embodiment 7

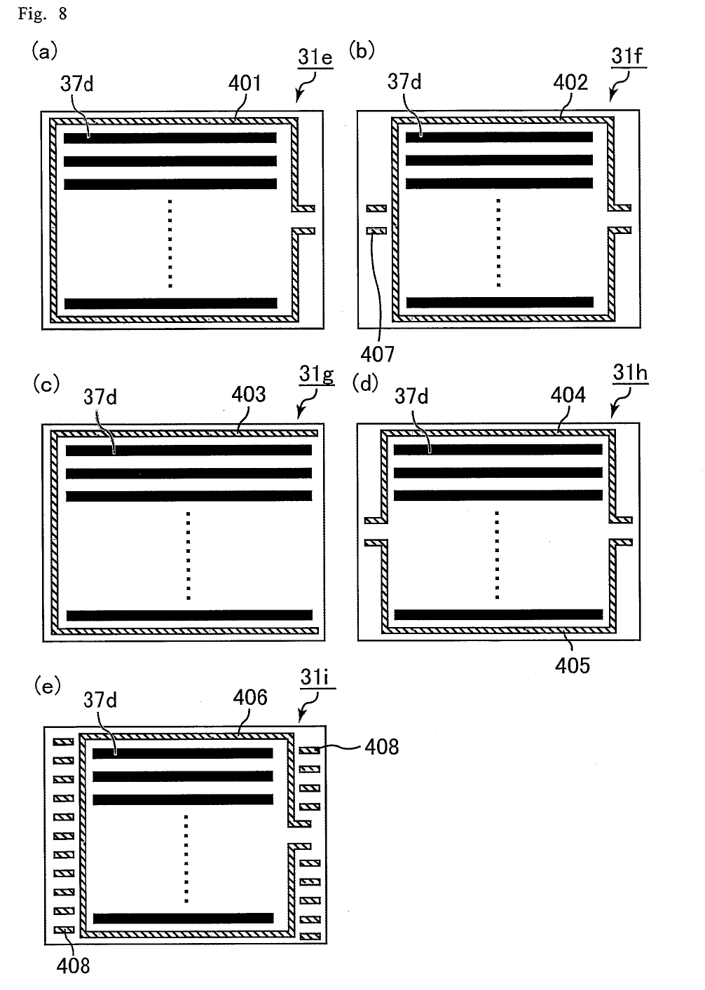

An example will be explained in the present embodiment in which the spacers described in Embodiment 5 are supplemented with an outer spacer and/or dummy spacers. FIG. 8 is a plan-view schematic diagram for explaining a layout pattern of outer spacers and/or dummy spacers according to the present embodiment.

As illustrated in FIGS. 8(a) to (e), transfer receiving substrates 31e to 31i have formed thereon stripe-like spacers 37d and, in addition, partly non-contiguous outer spacers 401 to 406 that surround the spacers 37d.

The shape of the openings formed in the outer spacers 401 to 406 is not particularly limited. Likewise, the number of openings is not particularly limited. For instance, the outer spacers may have a narrow opening, as illustrated in FIG. 8(a), (b), (d), (e), or a large opening, as illustrated in FIG. 8(c).

The outer spacers 401 to 406 may be formed non-contiguously with the spacers 37d that are formed in the pixels, so long as the spaces between the substrates are continuously connected.

Providing outer spacers 401 to 406 such as the above enables good evacuation during the film formation step in the above-described vacuum chamber. If the above-described clamping frame is used, in particular, the openings for evacuation are preferably small, since this makes for a smaller clamping frame and renders the operation easier. The openings can be reduced by adopting designs such as those of the outer spacers 401, 402, 404, 406. In designs such as those of the outer spacers 401, 402 and 406, the openings are present at one side alone. Accordingly, only that portion need be fixed by way of a jig.

As described above, the substrate spacing between the donor substrate and the transfer receiving substrate must be maintained as constant as possible in the film formation step. Such being the case, the transfer receiving substrates 31g, 31h preferably exhibit symmetry, at least left-right symmetry or up-down symmetry, as in the case of the outer spacers 403, 404.

Alternatively, there may be further provided dummy spacers, so that the combination of dummy spacers and outer spacers is symmetrical. A comparison between the outer spacer 401 and the outer spacer 402 illustrated in FIG. 8(a) and FIG. 8(b) shows that symmetry is enhanced by providing the dummy spacers 407 in FIG. 8(b).

Likewise, a comparison between the outer spacer 401 and the outer spacer 406 illustrated in FIG. 8(a) and FIG. 8(e) reveals that symmetry is enhanced by providing the dummy spacers 408 in FIG. 8(e).

Providing thus the dummy spacers 407, 408 allows maintaining the substrate spacing between the donor substrate and the transfer receiving substrate yet more uniformly, and allows simplifying the configuration of the jig that fixes the two substrates.

The shape and layout pattern of the dummy spacers are not limited to the above-described ones, and may be appropriately set in accordance with, for instance, the shape of the spacers, in such a way so as enable uniform pressing of the abovementioned two substrates.

The above embodiments can be suitably combined with each other without departing from the scope of the present invention.

The present application claims priority, under the Paris convention and pursuant to the laws of national-phase countries, for Japanese Patent Application No. 2009-090955, filed Apr. 3, 2009, the entire contents whereof are incorporated herein by reference.

### EXPLANATION OF REFERENCE NUMERALS

10, 110, 125 donor substrate
11, 32 support substrate
12, 130 photothermal conversion layer
13 protective layer
20, 120 organic layer
21, 23 first organic layer
22 second organic layer
24, 25 organic layer
30, 31, 31a to 31i transfer receiving substrate
33 first electrode
34 hole-injection layer
35 hole-transport layer
36 partition
37, 37a to 37d spacer
40 radiation
45 vacuum chamber
46 space
50, 150, 155, 160 transfer film
51, 52, 151, 152, 156, 157, 158 material
60 electron-transport layer
61 electron injection layer
62 second electrode
70 sealing glass substrate
80, 90, 95 organic electroluminescent element
200 pixel
401 to 406 outer spacer
407, 408 dummy spacer
d1, d2 film thickness
w1 width

1. A donor substrate comprising a photothermal conversion layer and a donor layer, wherein
the donor layer has a first organic layer arranged on a side of a transfer surface, and a second organic layer arranged on a side of the photothermal conversion layer,
the first organic layer and the second organic layer are formed of vaporizable organic materials having dissimilar vaporization-starting temperatures, and
the organic material that forms the first organic layer has a vaporization-starting temperature higher than that of the organic material that forms the second organic layer.

2. The donor substrate according to claim 1, wherein the second organic layer is a multilayer film or a mixed film formed of a plurality of organic materials.

3. The donor substrate according to claim 2, wherein the second organic layer is a multilayer film which is formed such that the vaporization-starting temperature thereof increases from the side of the photothermal conversion layer towards the side of the transfer surface.

4. The donor substrate according to claim 1, wherein the photothermal conversion layer is a metal plate doubling as a support substrate, the metal plate having a thickness ranging from 10 to 200 μm.

5. The donor substrate according to claim 1, wherein the donor layer contains at least one selected from among an electroluminescent organic material, a hole-transporting organic material and an electron-transporting organic material.

6. The donor substrate according to claim 5, wherein the donor layer contains an n-type dopant material in addition to the hole-transporting organic material.

7. The donor substrate according to claim 5, wherein the donor layer contains a p-type dopant material in addition to the electron-transporting organic material.

8. The donor substrate according to claim 5, wherein the donor layer is formed of an organic material whose vaporization-starting temperature ranges from 100° C. to 500° C.

9. A process for production of a transfer film using the donor substrate according to claim 1,
the process comprising:
an arrangement step of arranging the donor substrate and a transfer receiving substrate opposite each other; and
a film formation step of irradiating radiation onto the photothermal conversion layer of the donor substrate, to vaporize the organic materials that make up the donor layer and cause the organic materials to be deposited on a main surface of the transfer receiving substrate, thereby forming a transfer film, wherein
in the film formation step, both the organic material that forms the first organic layer and the organic material that forms the second organic layer are vaporized.

10. The process for production of a transfer film according to claim 9, wherein substantially a film thickness ratio of the organic layers that make up the donor layer and a volume mixing ratio of the organic materials in the transfer film are proportionally identical.

11. A process for production of an organic electroluminescent element using the process for production of a transfer film according to claim 9, wherein
the substrate receiving transfer is a device substrate on which at least a first electrode is formed,
the donor layer contains at least one selected from among an electroluminescent organic material, a hole-transporting organic material and an electron-transporting organic material;
in the film formation step, at least one layer selected from among an emissive layer, a hole-transport layer and an electron-transport layer is formed on the first electrode, and wherein
the process further comprises an electrode formation step of forming a second electrode on the layer that is formed in the film formation step.

12. The process for production of an organic electroluminescent element according to claim 11, wherein in the film formation step, a pressure in a space between the donor substrate and the substrate receiving transfer is lower than a pressure of an atmosphere under which the step is performed.

13. The process for production of an organic electroluminescent element according to claim 11, wherein
the substrate receiving transfer has a spacer at an outer edge of a region at which the transfer film is formed, and
in the arrangement step, the substrate receiving transfer and the donor substrate are held, with the spacer being in contact with the donor substrate.

14. The process for production of an organic electroluminescent element according to claim 13, wherein
the film formation step is carried out in a vacuum atmosphere; and
the spacer is provided with an opening for discharge of a gas between the transfer receiving substrate and the donor substrate.

15. The process for production of an organic electroluminescent element according to claim 13, wherein a columnar and/or stripe-like spacer is used as the spacer.

16. The process for production of an organic electroluminescent element according to claim 13, wherein
the emissive layer is rectangular; and
the spacer is formed at four corners in the outer edge of the emissive layer.

17. The process for production of an organic electroluminescent element according to claim 13, wherein
the emissive layer is rectangular; and
the spacer is formed at the outer edge of the emissive layer, along four sides thereof.

18. The process for production of an organic electroluminescent element according to claim 15, wherein the stripe-like spacer is formed along a longitudinal direction or transversal direction of the transfer receiving substrate; and the spacer is formed up to one end of the substrate.

19. The process for production of the organic electroluminescent element according to any of claim 13, wherein
the transfer receiving substrate further has, in addition to the spacer, an outer spacer that surrounds the spacer; and
at least part of the outer spacer is formed non-contiguously.

20. The process for production of an organic electroluminescent element according to claim 19, wherein an arrangement shape of the outer spacer is symmetrical with respect to the longitudinal direction or the transversal direction of the substrate.

21. The process for production of an organic electroluminescent element according to claim 19, wherein
an arrangement shape of the outer spacer is asymmetrical with respect to the longitudinal direction or the transversal direction of the substrate; and
the transfer receiving substrate further has a dummy spacer, and a combination of the outer spacer and the dummy spacer is symmetrical with respect to the longitudinal direction or the transversal direction of the transfer receiving substrate.

22. The process for production of the organic electroluminescent element according to claim 11, wherein
the transfer receiving substrate has a partition that surrounds a region at which the transfer film is formed; and
in the transfer film formation step, the transfer film is formed to a height reaching an end face of the partition on the donor substrate side.
